(19) United States
(12) Patent Application Publication
(10) Pub. No.: US 2022/0173014 A1
(43) Pub. Date: Jun. 2, 2022

(54) LIQUID COOLING SYSTEM

(71) Applicant: SHENZHEN APALTEK CO., LTD., Shenzhen (CN)

(72) Inventor: Qineng XIAO, Dongguan (CN)

(21) Appl. No.: 17/675,386

(22) Filed: Feb. 18, 2022

Related U.S. Application Data
(63) Continuation of application No. 16/789,892, filed on Feb. 13, 2020.
Application No. 16/789,892 is a continuation-in-part of application No. 15/541,706, filed on Jul. 5, 2017, now Pat. No. 10,609,841.

(51) Int. Cl. H01L 23/473; H01L 23/40; H01L 23/467

(52) U.S. Cl. CPC H01L 23/473; G06F 1/20; H01L 23/467; H01L 23/4006

(57) ABSTRACT

A liquid cooling system includes a heat dissipating device with cooling pipes and a radiation structure arranged on the cooling pipes; a pump device, integrally arranged between the cooling pipes and generating power so that a coolant circulates within the cooling pipes; a heat absorbing device, attached to a heating device and having a heat conduction effect with the heating device; and a combination means for connecting a connecting unit to the pump device. On the basis of existing products, a liquid pump main body and a radiator are integrally arranged together, and the heat absorbing device is connected to the liquid pump main body via the combination means. In addition, the leakage at the tube connector and the occupied space is significantly reduced, the heat transfer effect is significantly improved, and the production and assembly costs are reduced, so that product assembly is convenient and efficiency is high.

### CROSS-REFERENCE TO RELATED APPLICATION

The present application is a continuous application of U.S. Ser. No. 16/789,892 filed on Feb. 13, 2020, which is a continuation-in-part application of U.S. Ser. No. 15/541,706 filed on Jul. 5, 2017, now patent no. U.S. Pat. No. 10,609,841B2 issued Mar. 31, 2020, which is National Stage Entry of PCT/CN2017/070823 filed Jan. 11, 2017, which claims priority to CN201510769643.7 filed Nov. 12, 2015. The entire disclosures of the above applications are all incorporated herein by reference.

### BACKGROUND

### Technical Field

The present invention relates to a liquid cooling system, and more particularly to a liquid cooling system which includes a pump device integrally arranged inside a heat dissipating device and a heat absorbing device connected to the pump device via a combination means.

### Description of Related Art

At present, water-cooling radiators are commonly used as the cooling devices for cooling down devices such as computer CPU, graphic cards, chips of electronic equipment and are basically consist of three major components, which are heat absorbing device, pump device and heat dissipating device. The three components are connected to form a closed loop for liquid circulation in which the heat absorbing device is connected to the heat dissipating device while the pump device provides power to liquid circulation in the loop. The drawback of this design is that the three components are assembled and affixed by external connection through connecting pipes, thus a relatively large space is utilized and its installation and operation is inconvenience. In view of the relatively high installation requirement for space and poor flexibility in installation, its application is very limited. China patent application number 200580050009.2 is targeted at solving the present problem and provides a cooling system for computer system which incorporates a heat exchange interface, a liquid storage compartment and a pump as one part of an integrated component, of which the pump is superimposed on the heat absorbing device. This integration arrangement will lead to the heat absorbing device having a size which is not suitable for fitting into the small space, the pump device which is arranged on top of the heat absorbing device will be easily affected by the high temperature and resulted in damage, thus its lifespan is affected. At present, the position of the pump device in this kind of heat dissipating device is unreasonable, resulting in low work efficiency of the pumping power, thus making the cooling effect unsatisfactory and the service life is limited.

### SUMMARY

An object of the present invention is to solve the technical problem, in view of the above-mentioned drawbacks in the existing arts, by providing a liquid cooling system and a radiator for application in the liquid cooling system.

According to the present invention, the foregoing and other objects and advantages are attained by a liquid cooling system, characterized in that, the system comprises:

a heat dissipating device, which comprises cooling tubes and a radiator structure arrangement on the cooling tubes;

a pump device, integrally mounted between the cooling tubes to generate power for circulation of coolant inside the cooling tubes;

a heat absorbing device for attaching to a heat-generating component and being arranged for heat conduction with the heat-generating component;

a connecting unit configured for connecting the pump device in one-side, another side of the connecting unit being combined with the heat absorbing device; and

a combination means for connecting the connecting unit to the pump device;

wherein the system further comprises a liquid chamber arranged for storing a predetermined amount of coolant, that the coolant is arranged for accumulating and transmitting the heat dissipated to the coolant from the heat-generating component, the liquid chamber is provided to at least one end of the cooling tube of the heat dissipating device; the pump device comprises a pump chamber and a pump power body, at least one of the cooling tube inlet and the cooling tube outlet is connected to one of the two ends of the pump chamber, the pump power body pumps out the coolant from the cooling tube outlet to circulate through the cooling tube;

wherein the liquid chamber is divided into a top liquid chamber and a bottom liquid chamber which are positioned at two opposite sides of the cooling tubes, wherein the top liquid chamber has a partition panel for liquid partition therein to divide the liquid chamber into an inlet chamber and an outlet chamber, wherein the cooling tubes are divided into an inlet cooling tube and an outlet cooling tube; the inlet cooling tube interconnects the inlet chamber and the bottom liquid chamber; the outlet cooling tube interconnects the outlet chamber and the bottom liquid chamber; and

wherein a number of the inlet cooling tubes is N and the N number of inlet cooling tubes are aligned in a side-by-side manner, wherein a section of the N number of inlet cooling tubes are disconnected to define a window in such a manner that N number of inlet cooling tube openings are formed side-by-side at a top side and a bottom side of the window, wherein the pump chamber has N number of inlet openings and outlet openings corresponding to the window such that the pump chamber is connected to the inlet cooling tube openings at the top side and the bottom side in a sealed manner through the N number of inlet openings and outlet openings, wherein a number of the outlet cooling tubes is M, where M>N≥1 (N is an integer), and the M number of outlet cooling tubes are arranged in a side-by-side manner and positioned at two sides of the inlet cooling tubes.

The present invention is based on the existing product and employs an integral arrangement of the pump device and the heat dissipating device. In this way, the pump device is positioned in the middle of the radiator unit. The fan for heat dissipation not only is used to bring away the heat from the radiator unit, but also to bring away the heat generated from the pump power device. Accordingly, the motor life is prolonged. Also, the leakage at the tube connector and the space requirement is greatly reduced. The pump device is connected to four inlet and eight outlet cooling tubes, which greatly increases the heat exchange effect. The power fan has five fan blades with a silicon steel sheet surrounded inside and a shaft of stainless steel employed. The shaft of stainless steel provides simple processing, lower cost and durable, so that the resulting product has performance stability. Accordingly, this not only increases the strength of the bearing, but also solves the wearing problem of the central axis and bushing caused by the impeller bearing working in the water for a long time, thus greatly reducing the noise of the product and providing a very superior balancing effect, thus the lifespan is greatly increased. The cost of manufacture and assembly is also reduced. Therefore, the product assembly is convenience and efficient, and the cost can be controlled.

### BRIEF DESCRIPTION OF DRAWING

In order to more clearly illustrate the technical solution of the embodiments of the present invention, the followings briefly described the drawings accompanying the description of embodiments. It will be apparent that the following drawings are merely exemplary embodiments of the present invention. For person of ordinary skill in the art, under the premise of non-creative work, other drawings can also be obtained based on these drawings. In the drawings:

FIG. 1 is an exploded view of a liquid cooling system according to a preferred embodiment of the present invention;

FIG. 2 is a structural illustration of a radiator unit according to a preferred embodiment of the present invention;

FIG. 3 is an illustration of an internal structure of a top water chamber according to a preferred embodiment of the present invention;

FIG. 4 is an A-A′ cross-sectional view of FIG. 2;

FIG. 5 is an illustration of a radiator unit, illustrating the structure when its bottom water chamber is not connected according to a preferred embodiment of the present invention;

FIG. 6 shows a perspective view of a liquid cooling system according to a preferred embodiment of the present invention;

FIG. 7 shows another perspective view of a liquid cooling system according to a preferred embodiment of the present invention;

FIG. 8 shows a top view of a liquid cooling system with the water-pump cover being removed;

FIG. 9 shows a cross-sectional view of a liquid cooling system according to a preferred embodiment of the present invention;

FIG. 10 shows another cross-sectional view of a liquid cooling system according to a preferred embodiment of the present invention;

FIG. 11 shows a perspective view of a liquid cooling system according to a preferred embodiment of the present invention;

FIG. 12 shows another perspective view of a liquid cooling system according to a preferred embodiment of the present invention;

FIG. 13 shows a top view of a liquid cooling system with the water-pump cover being removed;

FIG. 14 shows a cross-sectional view of a liquid cooling system according to a preferred embodiment of the present invention;

FIG. 15 shows another cross-sectional view of a liquid cooling system according to a preferred embodiment of the present invention.

### DETAILED DESCRIPTION

In order to make the objects, technical solutions and advantages of the present invention more clearly understood, the various embodiments are further described with the accompanying drawings in the followings. These drawings figures form a part of the embodiment, wherein the embodiment in which the present invention may be realized is described. It is to be understood that other embodiments may be used, or structural and functional modifications may be made to the embodiments described herein without departing from the scope and spirit of the present invention.

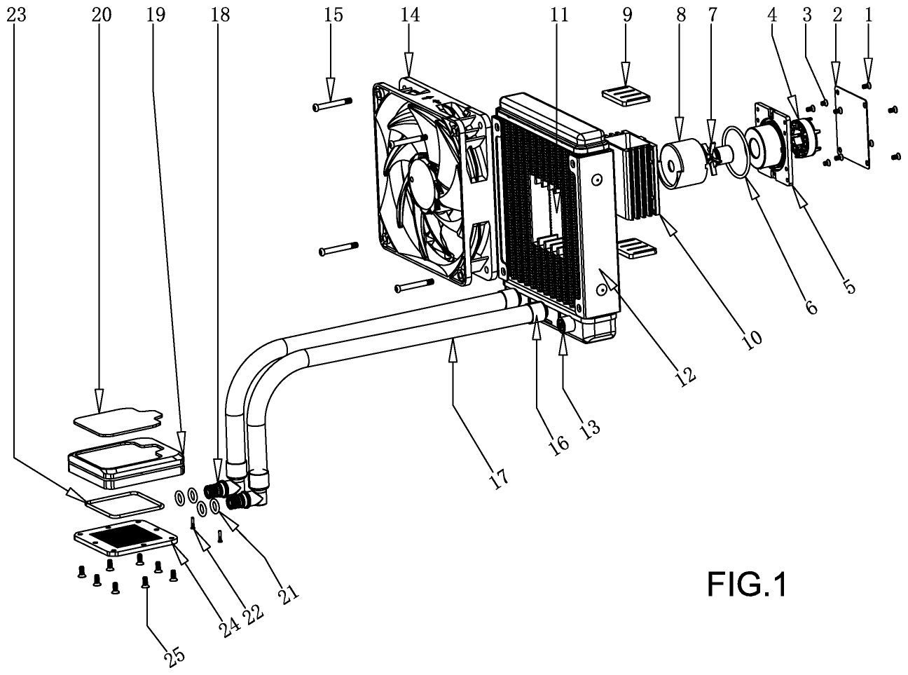

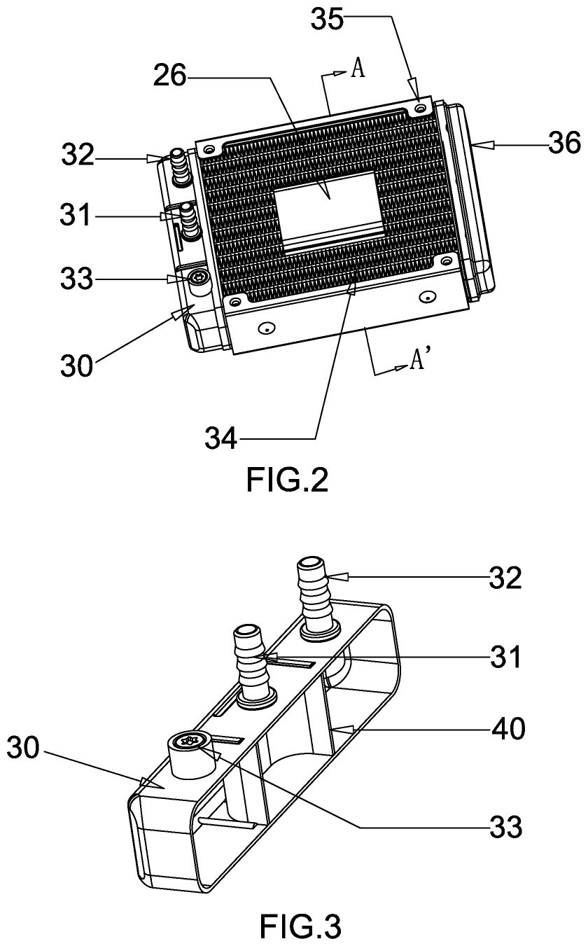

According to FIG. 1 of the drawings, an exploded view of the product as a whole according to a preferred embodiment of the present invention is illustrated; in conjunction with FIG. 1 and according to this embodiment, water is used as the coolant, the entire liquid cooling system comprises a fan 14, a radiator unit 12, a pump device, a tube unit 17, and a heat absorbing device, wherein the radiator unit 12 comprises a top water chamber 30, a bottom water chamber 36, as shown in FIG. 2, a partition panel welded inside the top water chamber 30 to divide the top water chamber 30 into water inlet chamber and water outlet chamber, a water inlet port 31 and a water outlet port 32 are provided on the water inlet chamber and water outlet chamber respectively, and a fill port 33 is arranged on a body of the water outlet chamber. According to this embodiment, the water inlet chamber is positioned in the middle portion of the top water chamber 30, the fill port 33 is channel through the water outlet port 32. Four flattened and harmonica-shaped tubes 34 which are arranged side by side are connected to the water inlet chamber to form an inlet cooling tube for connecting to the bottom liquid chamber 36, while eight harmonica-shaped tubes 34 on two sides of the bottom liquid chamber are used to form an outlet cooling tube and are positioned side by side on two sides of the inlet cooling tubes, with four tubes on one side, then through connecting to the bottom water chamber 36 to the water outlet chamber. In this way, the water inlet port 31 is connected to and channel through the water outlet port 32 through connecting to the harmonica-shaped tubes 34 with four inlets and eight outlets to form a loop. In addition, fins for heat dissipation are arranged on the external side of the harmonica-shaped tubes 34. As shown in FIG. 2 and FIG. 1 of the drawings, according to this embodiment, the inlet cooling tube is disconnected in a middle section to form a window 11, and four tube openings of the harmonica-shaped tubes 34 which are arranged side by side are provided on each of a top side and a bottom side of the window 11. A water-pump chamber 10 has a top end opening and a bottom end opening which are welded and connected to a main panel unit of water-pump chamber 9. On the main panel unit of water-pump chamber 9, connecting ports which are complementary to the harmonica-shaped tubes 34 are provided and are connected to the openings of the harmonica-shaped tubes 34 on the top side and the bottom side at the disconnected portion through sealed brazing. In this embodiment, there are four corresponding connecting ports. The water-pump chamber 10 has a side opening. The water-pump chamber 10 and the main panel unit of water-pump chamber 9 are constructed into a pump chamber 26. Referring to FIG. 1 of the drawings, an installation process of the power pumping body is: a water-pump stator 4 is pressed to the inside of a water-pump holder 5 by using jig and fixture, a water-pump rotor 7 has a plurality of blades and five blades are used (of course, seven or nine blades can also be used in other embodiments) in which a silicon steel sheet is winded inside and a shaft of stainless steel is employed; the water-pump rotor 7 is placed in the axial hole of the water-pump holder 5 and then placed inside the water-pump body 8 so that a water-pump stator body is formed; then place them together in the water-pump chamber 10 which is positioned on top of the radiator unit 12, put on a water-pump sealing ring 6 and put on water-pump screws 3 for locking at one time, then use electric or manual screwdriver to lock into position; and then cover a water-pump cover 2 on top of the power pumping body which is locked into position, finally, sequentially put on water-pump cover screws 1 and lock into position and sealing the side opening of the water-pump chamber 10; the entire structure and size of the pump chamber 26 is complement to the window 11, the pump chamber 26 and the power pumping body form the entire structure of the pump device. After installation in this way, the entire pump device is integrated completely into the radiator unit 12 to form an integral structure, which is shown in FIG. 2.

Again, referring to FIG. 1 of the drawings, two tubes 17 are connected to tube connectors 18 respectively, a sealing ring for tube connector 21 is connected to one end of the tube connector 18, then a silicon casing tube 16 is coupled to the other end of each of the two tubes 17 such that a connecting tube body is formed; lastly, the two tube bodies are connected to the water inlet port 31 and the water outlet port 32 respectively by using fixtures such that the tube bodies are connected to the assembled radiator unit 12. The other end of the tube body is connected to the heat absorbing device, the heat absorbing device comprises a water-cooling head chamber 19, a sealing ring for water-cooling head chamber 23 is coupled to the sealing grooves on the water-cooling head chamber 19, a copper plate for heat absorption 24 is put on top of the sealing ring for water-cooling head chamber 23 and copper plate screws 25 are put on at one time and locks into position, and finally, a water-cooling head LED decoration unit 20 is installed on top of the water-cooling head chamber 19; tube connectors 18 are linked to connecting holes on one side of the water-cooling head chamber 19 and lock into position by connector locking screws 22 such that an integrated circulating water loop is formed. Fan locking screws 15 is used to lock the fan 14 on the radiator unit 12 to assemble the integrated water cooling system.

Referring to FIG. 3 of the drawings, an internal structure of a top water chamber 30 according to a preferred embodiment of the present invention is illustrated. The partition panel 40 is provided in the middle portion inside the top water chamber 30 to divide the top water chamber 30 into a water inlet chamber and a water outlet chamber, the water inlet port 31 is provided on an outer side of the water inlet chamber which is in the middle portion of the water inlet chamber, a water outlet port 32 and a fill port 33 are provided on the two sides of the water outlet chamber respectively, the entire top water chamber 30 is sealed and welded together with the cooling tubes.

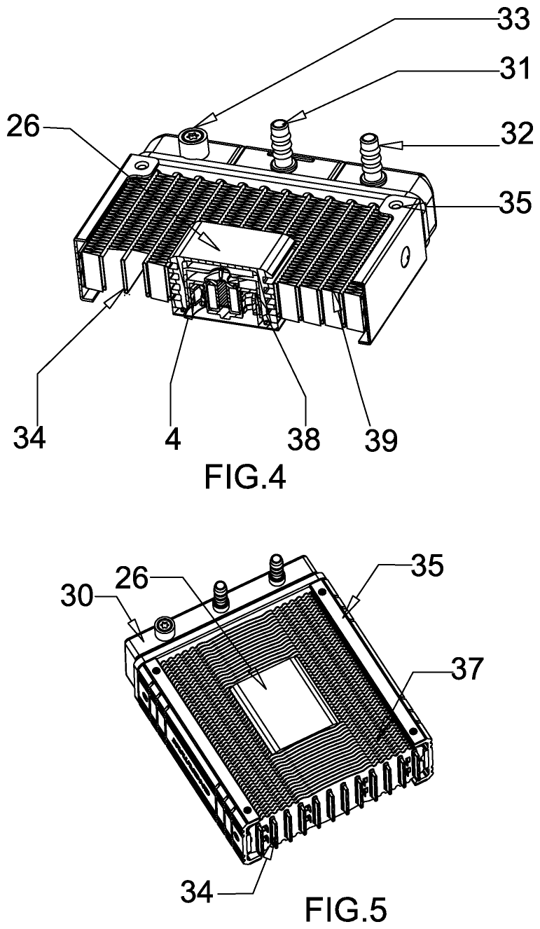

FIG. 4 is a cross-sectional view taken along the line A-A′ in FIG. 2. The harmonica-shaped tube 34 has a flattened structure, the four harmonica-shaped tubes 34 in the middle are sealed and connected to the pump chamber 26, the coolant flows to the water-pump channels 38 and is pumped out through the power pumping body. Here, the brazed fins 39 are employed in this embodiment. The fins for heat dissipation employs brazing to connect between the harmonica-shaped tubes. Two main side panels for fan mounting 35 are provided at the two outermost sides respectively.

FIG. 5 is an illustration of a radiator unit when the bottom water chamber is not connected. As shown in the figure, there are a total of twelve (12) harmonica-shaped tubes 34, four of the tubes are connecting from the top water chamber 30, through the pump chamber 26, to the bottom water chamber, then from the four harmonica-shaped tubes which are aligned side by side on each of the two sides to return to the water outlet chamber to complete the loop. In FIG. 5, the fins for heat dissipation employ wavy soldered fins 37 coupled to the outer side of the harmonica-shaped tubes 34. The two outermost sides employ main side panels for fan mounting 35 for securing the radiator unit 12 into position and externally connecting the fan.

According to the cross-sectional view taken along the line A-A′ in FIG. 2 of the present invention, in summary, the power pumping body comprises a motor and a power fan blades, the power fan blades has five fan blades with a silicon steel sheet surrounded inside and a shaft of stainless steel is employed. The shaft of stainless steel provides simple processing, lower cost and durable, so that the resulting product has performance stability. Accordingly, this does not only increase the strength of the bearing, but also solving the wearing problem of the central axis and bushing caused by the impeller bearing working in the water for a long time, thus greatly reducing the noise of the product and providing a very superior balancing effect, which is a good way to improve the performance of the motor. With the use of physical centripetal force and centrifugal force, the shaft is placed in the pump holder 5 and hence the lifespan of the pump device is greatly extended. The water-pump stator 4 is winded by six-pole coil, which greatly increasing the performance of the motor while reducing the volume and size of the motor.

The copper plate for heat absorption 24 in the heat absorbing device employs the latest groove-cutting style copper base and is capable of using other metal materials such as alloyed copper, aluminum, aluminum alloy, alloy steel etc. The inner bottom surface of the bottom plate for heat exchange adopts a groove structure so that the coolant in the coolant chamber is endlessly close to the heat-generating devices, thus bringing away the heat from the heat-generating devices effectively.

In order to realize the above liquid-cooled radiator unit used in the liquid cooling system, this embodiment utilizes water as the coolant. Of course, other liquid which has the effect of coolant can also be used. For examples, sealed liquid nitrogen etc. can also be used. According to this embodiment, the water inlet chamber is positioned at the middle portion in the top water chamber while the fill port 33 and the water outlet 32 are channel through, and this is not a fixed arrangement and other arrangements can also be workable. For example, their position can be arranged in one side of the radiator unit. The harmonica-shaped tube connected to the water inlet chamber can also have another shape, or the number of harmonica-shaped tube can be one or more than one provided that the number of tubes connecting to liquid-cooled outlet tubes is not smaller than that of liquid-cooled inlet tubes. Of course, it is also possible to have a smaller number of tubes as long as the entire loop of coolant is realized because the thickness of the tubes can be varied and the flow rate of the coolant can be varied. In the present preferred embodiment, the number of liquid-cooled outlet tubes is two times of the number of liquid-cooled inlet tubes while the liquid-cooled outlet tubes are positioned at the two sides of the liquid-cooled inlet tubes.

The above is a specific embodiment of the present invention. In the embodiment, amongst the fan 14, the radiator unit 12, the pump device, the tubes and the heat absorbing device in the entire liquid cooling system, the fan 14 provides a faster cooling effect to the radiator unit 12. However, in the absence of fan 14, the present system is still workable. In the structure of the radiator unit 12, only one of the top water chamber 30 and the bottom water chamber 36 is required and can be defined as a water chamber, which can be located at one side of the cooling tube. As long as a water outlet port and a water inlet port are provided on the water chamber, and the water chamber is connected to the heat absorbing device such that the heat dissipating to the water from the heat generating component is accumulated and conveyed, that at this point the pump device can be positioned at any section of the cooling tube to provide power for the cooling water to circulate inside the cooling tubes. However, if water chamber is arranged on a top and a bottom of the radiator unit and the pump chamber is connected to one-way flowing cooling tubes, it is necessary to disconnect all the cooling tubes with one-way flowing and connect to two sides of the pump chamber so as to ensure that the system circulates under the power provided by the pump device.

It is obvious that in the above embodiment, the tube body is the tube unit. The length of the tube unit can be determined according to the actual product installation space, or can be as short as direct connection between the heat absorbing device and the radiator unit. Under certain space requirement, the water chamber can be substituted by the pump chamber directly and the tubes are directly connected to the two ends of the cooling tubes to form a water loop for circulation. The product based on the present invention can be very small in size in accordance with the space requirements of the electronic product. For examples, in its application on all-in-one computer, it requires only a very small space.

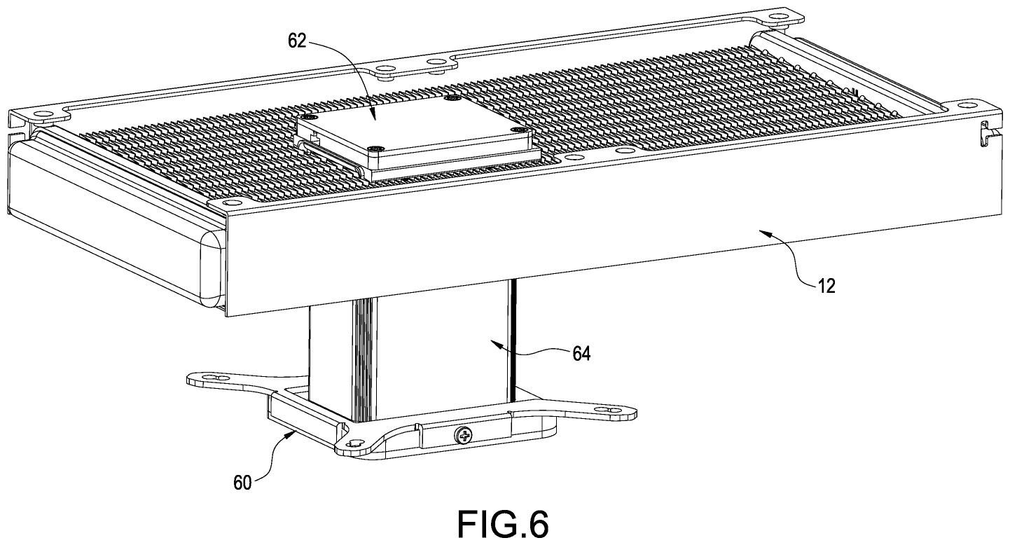

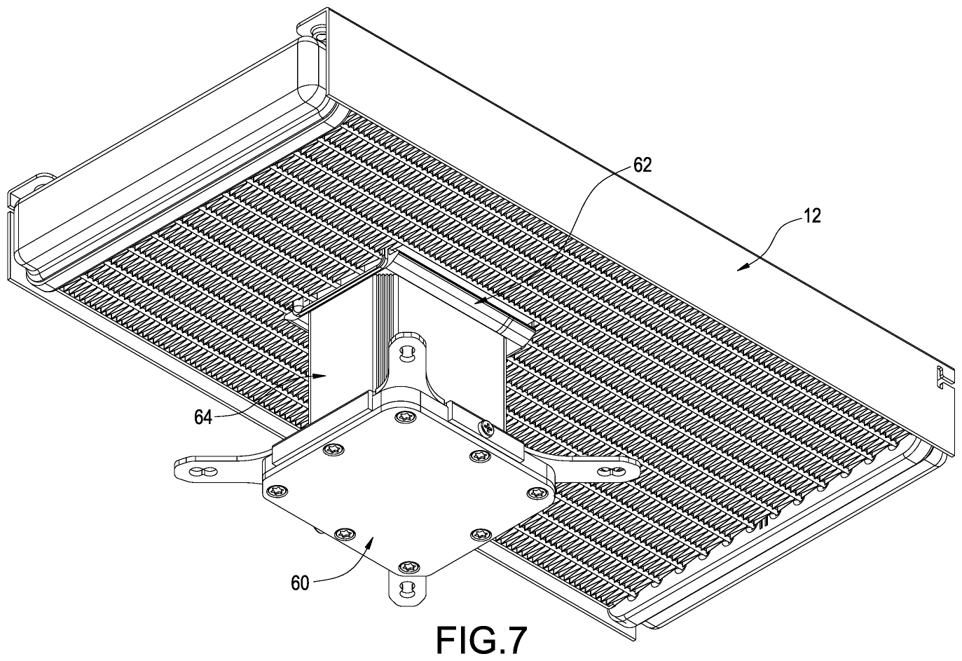

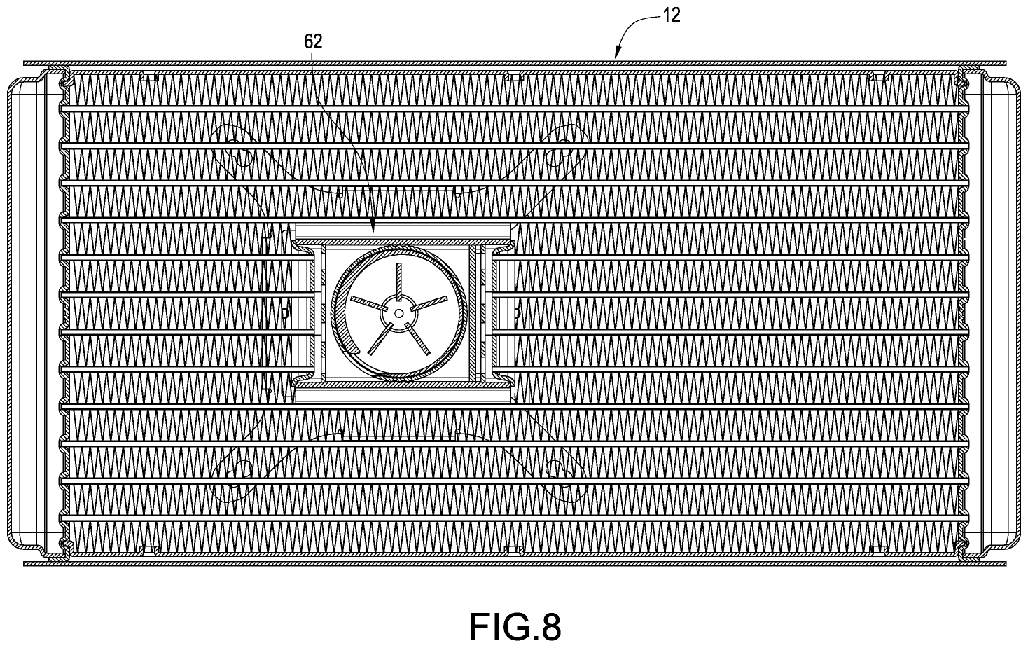

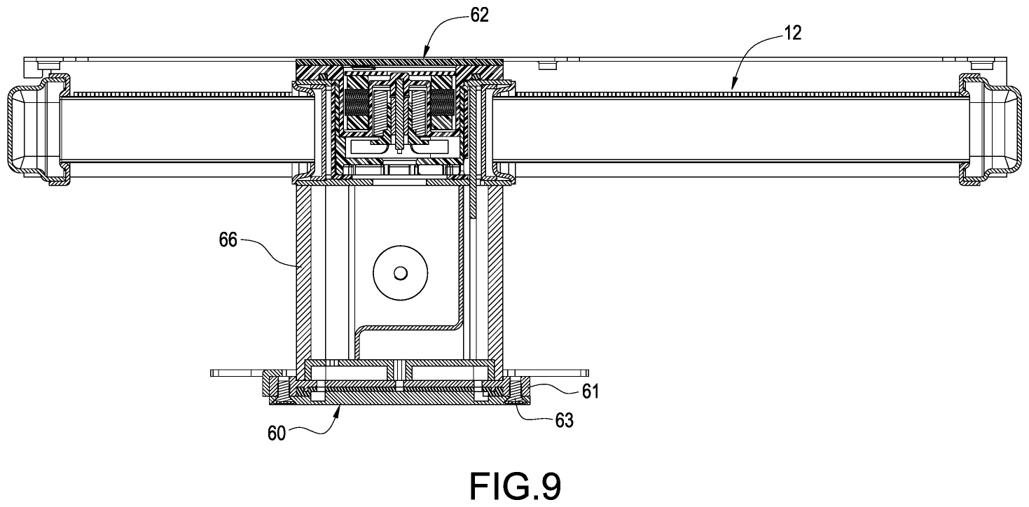

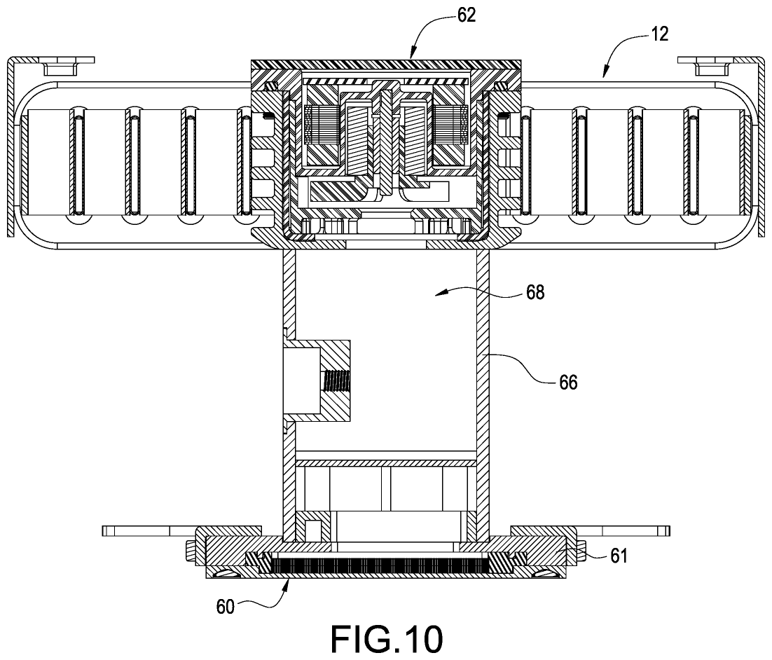

FIGS. 6 to 10 illustrate another embodiment of the liquid cooling system according to the present invention that a connecting unit 61 is connected to the pump device 62 via a combination means 64, instead of the tube unit 17 for connecting between the top water chamber 30 of the radiator unit 12 and the water-cooling head chamber 19 of the heat absorbing device as shown in FIG. 1. In this embodiment, a metal column 66 has two distal ends directly welded on the heat absorbing device 60 and the pump device 62, respectively, so the conventional leaking issue caused by deterioration of the tube material for typical flexible tube 17 can be prevented. The metal tube 66 forms a liquid channel 68 inside as well as a reservoir for enhancing the cooling capacity.

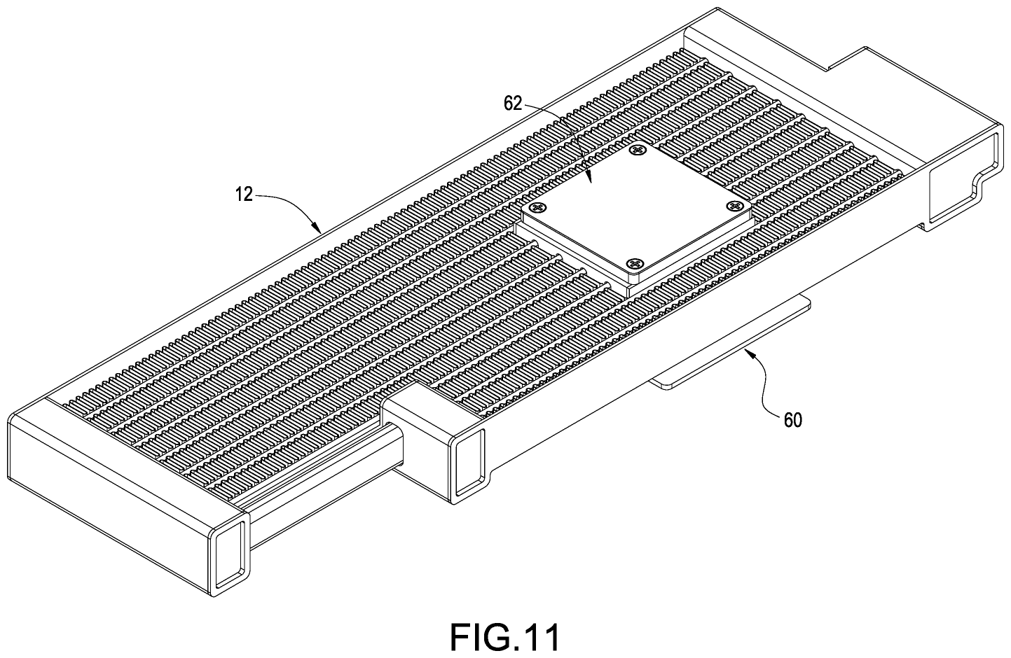

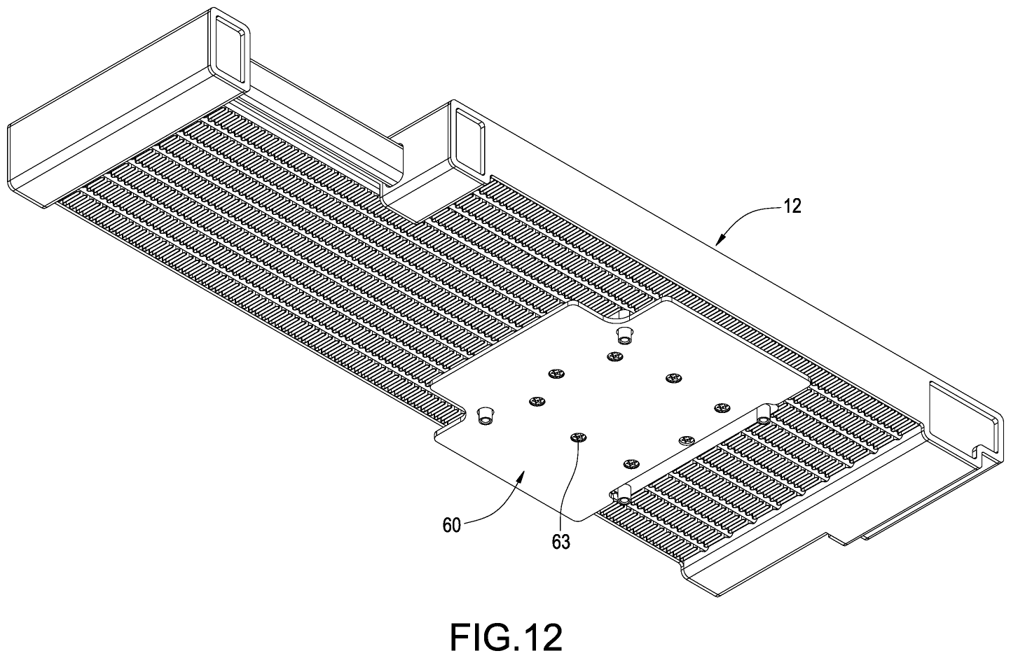

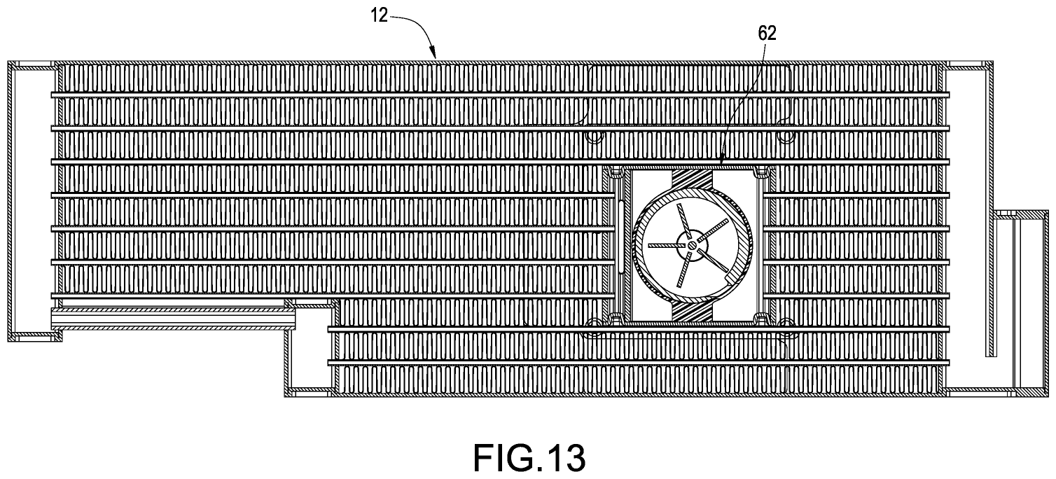

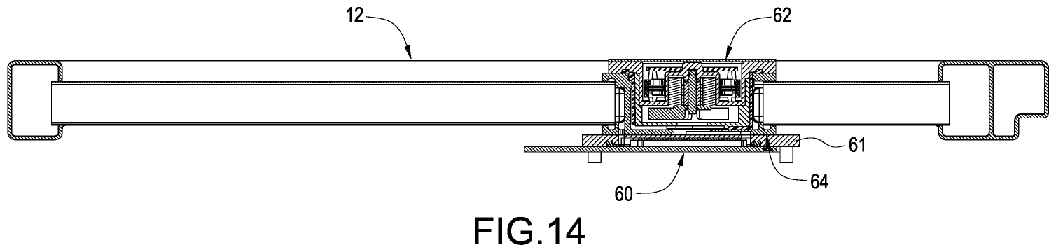

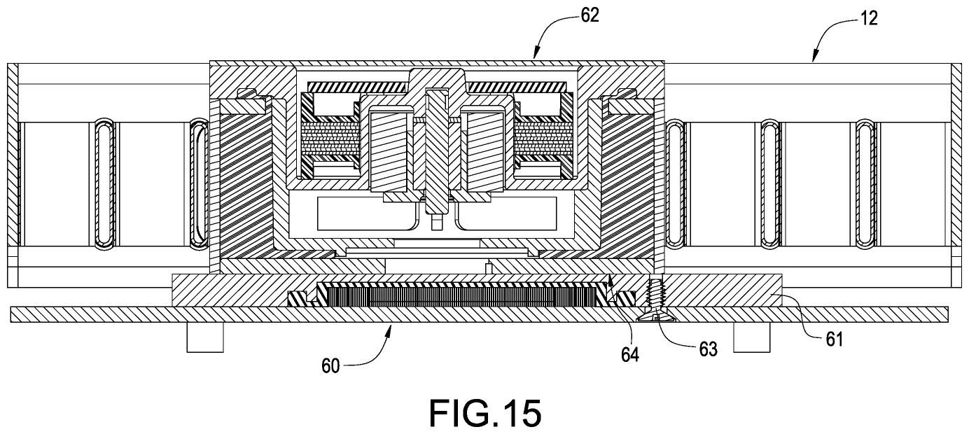

FIGS. 11 to 15 illustrate still another embodiment of the liquid cooling system according to the present invention that the heat absorbing device 60 and the pump device 62 are directly connected to each other by combination means so the volume of the liquid cooling system can be greatly reduced.

The combination means is defined for example as one of the welding or integrating way to combinate the connecting unit 61 and pump device 62, wherein the integrating way is defined the connecting unit 61 forming from one end of the metal column 66 or pump device 62, furthermore, one side of the connecting unit 61 is combined_with the heat absorbing device 60 by plurality screws 63 or welding, wherein the screws are arranged as the surrounding shape.

The liquid cooling system of the present invention provides superior heat dissipation to the heat-generating devices and is capable of preventing leakage at the tube connector, which can greatly enhance the lifespan of the pump device, lower the cost, and reduce the existing problem of electromagnetic noise from the motor.

The present invention is based on the existing product and employs an integral arrangement of the pump device and the radiator unit. The present invention includes the fan for heat dissipation to bring away the heat from the radiator unit, at the same time, the heat generated from the pump device is also blown away by the fan. Accordingly, the motor life is prolonged and the space requirement is greatly reduced. The pump device is connected to four inlet and eight outlet cooling tubes, which greatly increases the heat exchange effect. The cost of manufacture and assembly is reduced. Therefore, the product assembly is convenience and efficient, and the cost can be controlled.

One skilled in the art will understand that the embodiment of the present invention as shown in the drawings and described above is exemplary only and not intended to be limiting. It will thus be seen that the objects of the present invention have been fully and effectively accomplished. Its embodiments have been shown and described for the purposes of illustrating the functional and structural principles of the present invention and is subject to change without departure from such principles. Therefore, this invention includes all modifications encompassed within the spirit and scope of the following claims.

What is claimed is:

1. A liquid cooling system, comprising:
a heat dissipating device, which comprises a first chamber, a second chamber, a plurality of cooling tubes connected between the first chamber and the second chamber, and a plurality of fins arranged on the cooling tubes;
a pump device, integrally mounted between the cooling tubes for circulation of coolant inside the cooling tubes; and
a heat absorbing device, communicated with the pump device and receiving the coolant for attaching to a heat-generating component and being arranged for heat conduction with the heat-generating component,
wherein the heat dissipating device has an opening formed by disconnecting and removing portions of the plurality of cooling tubes and the fins, so that the pump device is capable of embedding in the opening and surrounded by the cooling tubes;
wherein, the portions of the plurality of cooling tubes disconnected by the opening are divided into multiple inlet tubes and multiple outlet tubes, and the pump device is jointed with the multiple inlet tubes and the multiple outlet tubes, and the coolant enters the pump device from the first chamber through the multiple inlet tubes, and then flows out of the pump device directly to the second chamber through the multiple outlet tubes.
